(19) United States
(12) Patent Application Publication
(10) Pub. No.: US 2017/0347130 A1
(43) Pub. Date: Nov. 30, 2017

(54) PROCESSING SYSTEM AND METHOD FOR LIVE VIDEO STREAMING BASED ON NETWORK CODING AND CONTENT DISTRIBUTION NETWORK

(71) Applicant: YUN SHANG COMPANY LIMITED, Shanghai (CN)

(72) Inventor: Jianfa LING, Shanghai (CN)

(21) Appl. No.: 15/600,791

(22) Filed: May 22, 2017

(30) Foreign Application Priority Data
May 26, 2016 (CN) 201610356496.5
Jan. 25, 2017 (CN) 201710061036.4

(51) Int. Cl. H04N 21/2187; H03M 13/00; H04L 29/06; G06F 17/30; H04N 21/236; H04L 29/08

(52) U.S. Cl. CPC H04N 21/2187; H04N 21/236; H04L 67/327; H04L 65/60; G06F 17/30516; H03M 13/6516; G06F 17/30784; H04L 65/4092

(57) ABSTRACT

The present invention provides a processing system and method for live video streaming based on network coding and content distribution network, applied in video streaming over a network. The processing system comprises a live broadcast source station, at least one edge server and a plurality of player nodes. The live broadcast source station generates a streaming video file and sends to the edge server, at which network coding is performed to output coded information to the player node. The data amount received by each of the player nodes is less than the original streaming file. The player nodes exchange the coded information with each other. A decoding process is performed when a player node accumulates enough coded information. If a player node cannot accumulate enough coded information, more coded information will be requested from the edge server until the streaming video file is decodable.

### FIELD OF THE INVENTION

The present invention relates to a processing system and method for network streaming, and more particularly to a processing system and method for live video streaming based on network coding and content distribution network.

### BACKGROUND OF THE INVENTION

To transmit a large amount of data over the Internet, a content distribution network (CDN) architecture is adopted, especially when the data is highly duplicated. A content distribution network for live video streaming in the prior art generally includes a live broadcast source station 110, edge servers 120 and player nodes 130, as shown in FIG. 1A.

In live video streaming according to the prior art, a streaming video file 140 is captured by the live broadcast source station 110, the video file is then segmented sequentially and the segments are sent to the edge severs 120 and the player nodes 130, as shown in FIG. 1B. It is noted that in the CDN architecture, each of the player nodes downloads a complete streaming video file from the edge server, so the total bandwidth consumption of the edge servers is huge.

To save bandwidth consumption of the edge servers, Peer-to-Peer (P2P) solutions have been adopted in the prior art. For example, multiple player nodes 130 may need the same part of the streaming video file 140. After receiving some parts of the streaming video file 140, any player node 130 may share its content with other adjacent player nodes 130. As long as the player node 130 can receive all of the missing parts of the file from other player nodes 130, a complete streaming video file 140 can be reconstructed. Assuming that the streaming video file 140 is segmented into four parts, which are received by four player nodes separately, as shown in FIG. 1C: a video segment a is received by a player node A, a video segment b is received by a player node B, a video segment c is received by a player node C, and a video segment d is received by a player node D. The player node A can receive the video segments b, c, d from the player nodes B, C, D, and reconstruct the streaming video file 140 from the video segments a, b, c and d.

However, another issue exists in data transmission among the player nodes. Multiple player nodes 130 may receive duplicated parts of the streaming video file 140, while other parts are missing. Assuming that the streaming video file 140 is segmented into three parts, file a, file b and file c, respectively. A video file a is received by a live broadcast node A, a video file b is received by a live broadcast node B, a video file c is received by a live broadcast node C, and a video file c is received by a live broadcast node D. As a result, duplicated transmission of the file c results in inefficient usage of bandwidth. More importantly, if some parts of the file are missing, the live broadcast node A would not be able to reconstruct the streaming video file 140.

### SUMMARY OF THE INVENTION

The objective of the present invention is to provide a processing system for live video streaming based on network coding and content distribution network, the process system being applied in live video streaming over a network.

To address the above issue, the present invention provides a processing system for live video streaming based on network coding and content distribution network. The processing system for live video streaming based on network coding and content distribution network of the present invention comprises a live broadcast source station, at least one edge server and a plurality of player nodes. The live broadcast source station is adapted to receive an audio video signal, and generate a streaming video file; the edge server is connected to the live broadcast source station, and is adapted to receive the streaming video file from the live broadcast source station, perform network coding on the streaming video file and output a plurality of pieces of coded information; each of the player nodes is connected to the edge server, and the player nodes are connected to each other via the network. Each of the player nodes receives the coded information from the edge server, and exchanges the coded information with other player nodes. As long as the amount of pieces of the coded information received by the player node reaches a decoding threshold, the player node decodes the received coded information and outputs the streaming video file. If the amount of received coded pieces is less than the decoding threshold, the player node requests more coded information from the edge server until the streaming video file is decodable.

To address the above issue, the present invention also provides a processing method for live video streaming based on network coding and content distribution network. The processing method comprises the following steps: a live broadcast source station receiving an audio video signal and generating a streaming video file; at least one edge server receiving the streaming video file from the live broadcast source station; the edge server performing a network coding program on the streaming video file and outputting multiple pieces of coded information; the edge server sending the coded information to an assigned player node; the player nodes exchanging the coded information with each other. When the amount of pieces of the received coded information reaches a decoding threshold, the player node decodes the received coded information by a decoding process program and outputs the streaming video file. If the amount of pieces of the received coded information is less than the decoding threshold, the player node requests more coded information from the edge server until the streaming video file is decodable.

As compared with the prior art, the present invention has the following technical advantages:

i) As compared with the network live video streaming broadcasting in the prior art, the present invention can save bandwidth consumption of the edge server, and can shorten the delay between generation of video signals and obtaining the video file by the users, thus offering end users better experiences when playing videos.

ii) After performing network coding on the video file according to the embodiments of the present invention, if network packet loss occurs when a player node receives other coded information, the player node can still perform decoding by receiving a new piece of coded information from other node without having to retransmit the lost coded information. This can improve the fluency of video playback.

Obviously, any product implemented in the present invention does not necessarily achieve all of the above technical effects simultaneously.

### BRIEF DESCRIPTION OF THE DRAWINGS

The figures described herein, as a constituting part of the present invention, provide further understanding of the present invention. The schematic embodiments and illustrations are used to explain the present invention, but not to impose improper limitations to the present invention.

FIG. 1A is a block diagram of the content distribution network according to the prior art;

FIG. 1B is a block diagram of player nodes and video files according to the prior art;

FIG. 1C is a block diagram of segmented streaming video file according to the prior art;

FIG. 2A is a block diagram of the content distribution network according to an embodiment of the present invention;

FIG. 2B is a block diagram of the edge server according to an embodiment of the present invention;

FIG. 2C is a block diagram of the player node according to an embodiment of the present invention;

FIG. 3 is a flow chart depicting the operation according to an embodiment of the present invention;

FIG. 4A is a block diagram depicting outputting of the streaming video file according to an embodiment of the present invention;

FIG. 4B is a block diagram depicting decoding of the coded information and outputting of the streaming video file according to an embodiment of the present invention; and

FIG. 5 is a block diagram of the system configuration according to another embodiment of the present invention.

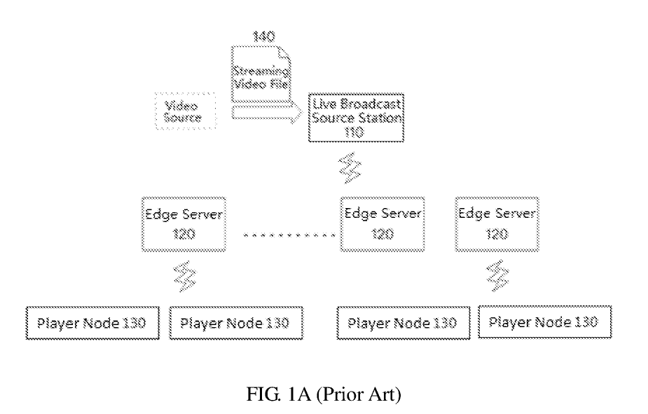

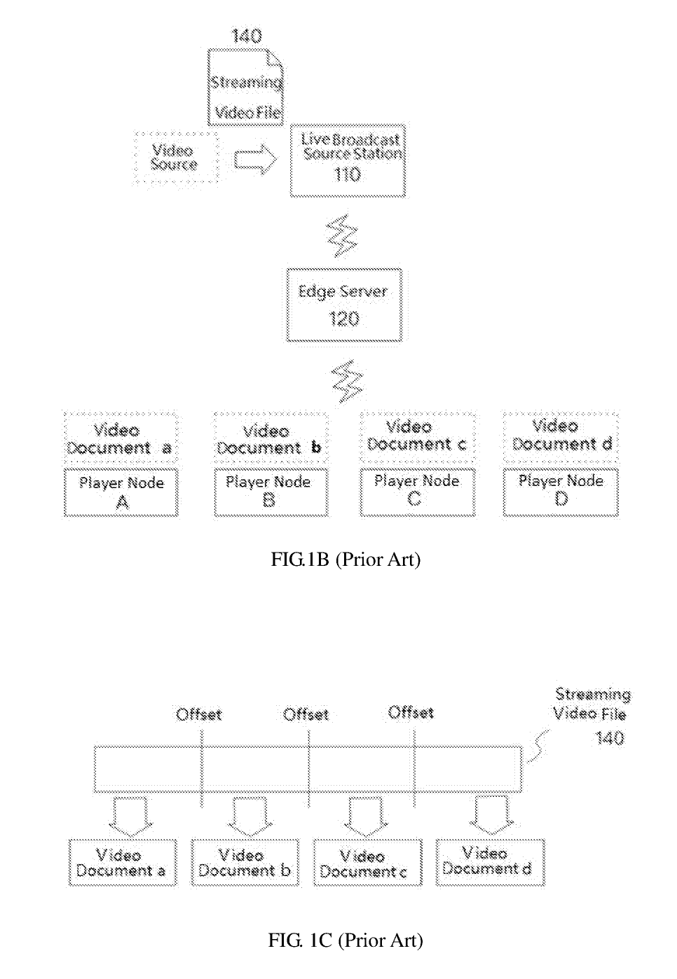

### DETAILED DESCRIPTION OF PREFERRED EMBODIMENTS

Please follow the explanations with the figures and embodiments to get a full understanding of the application, and to further apply the technical means to solve the related problems to achieve desired effects.

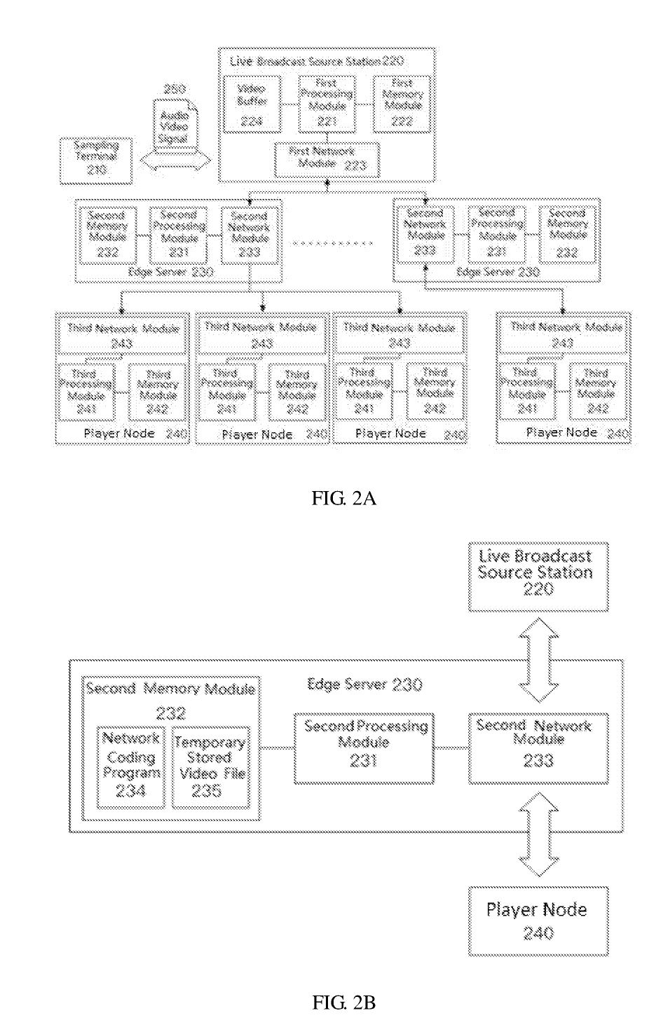

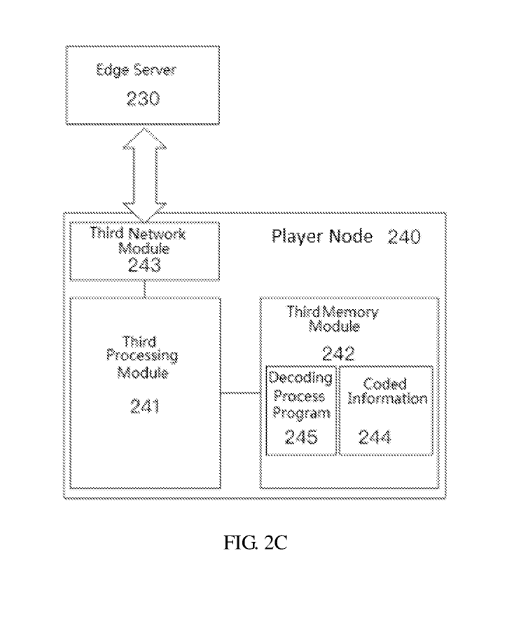

Please refer to FIG. 2A, FIG. 2B, FIG. 2C, the processing system 200 for live video streaming based on network coding and content distribution network according to an embodiment of the present invention comprises a sampling terminal 210, a live broadcast source station 220, at least one edge server 230, and a plurality of player nodes 240.

The live broadcast source station 220 is connected to the sampling terminal 210 and at least one of the edge servers 230 via the network. The edge server 230 is connected to at least one of the player nodes 240. The live broadcast source station 220 comprises a first processing module 221, a first memory module 222, a first network module 223 and a video buffer 224. The edge server 230 comprises a second processing module 231, a second memory module 232 and a second network module 233. The player node 240 comprises a third processing module 241, a third memory module 242 and a third network module 243.

The first processing module 221 is electrically connected to the first memory module 222, the first network module 223 and the video buffer 224. The second processing module 231 is electrically connected to the second memory module 232 and the second network module 233. The third processing module 241 is electrically connected to the third memory module 242 and the third network module 243. The second network module 233 is connected to the first network module 223 and the third network module 243 via the network. The second network module 233 receives a file request notification and a streaming video file 235 from the live broadcast source station 220. The third network module 243 receives the coded information 244 from the edge server 230 or the coded information from other player nodes 240. The second memory module 232 records the network coding program 234 and the streaming video file 235. The third memory module 242 stores the coded information 244 and the decoding process program 245.

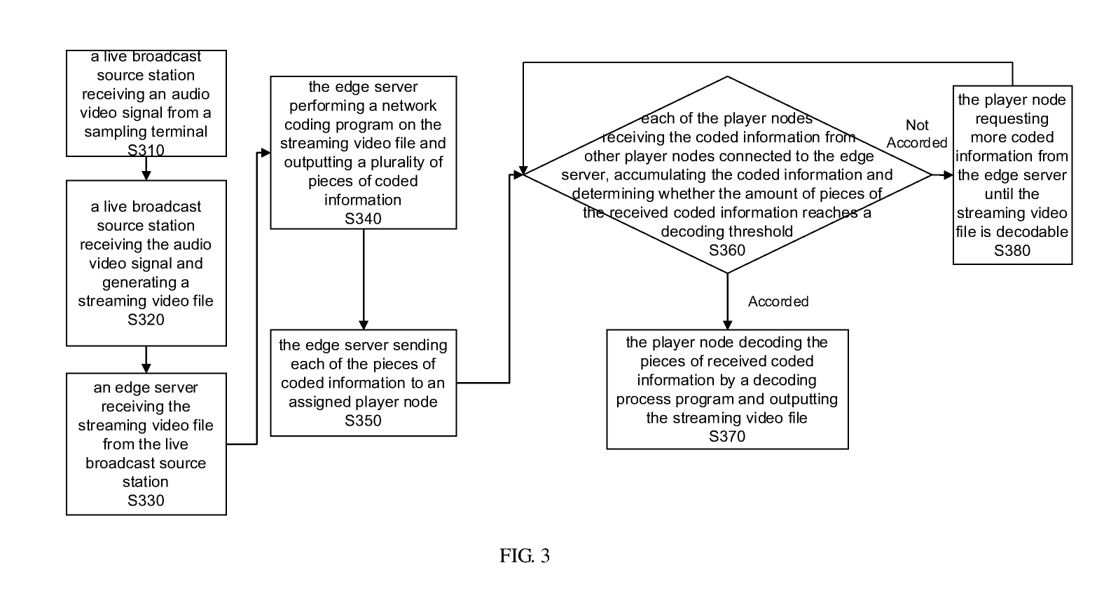

To understand the operation of the embodiments of the present invention more clearly, please refer to FIG. 3. The processing method for live video streaming of the present invention comprises the following steps:

Step S310: a live broadcast source station receiving an audio video signal from a sampling terminal;

Step S320: a live broadcast source station receiving the audio video signal and generating a streaming video file;

Step S330: an edge server receiving the streaming video file from the live broadcast source station;

Step S340: the edge server performing a network coding program on the streaming video file and outputting a plurality of pieces of coded information;

Step S350: the edge server sending each of the pieces of coded information to an assigned player node;

Step S360: each of the player nodes receiving the coded information from other player nodes connected to the edge server, accumulating the coded information and determining whether the amount of pieces of the received coded information reaches a decoding threshold;

Step S370: if the amount of pieces of the received coded information reaches the decoding threshold, the player node decoding the pieces of received coded information by a decoding process program and outputting the streaming video file; or

Step S380: if the amount of pieces of the coded information received is less than the decoding threshold, the player node requesting more coded information from the edge server until the streaming video file is decodable.

First, the first memory module 222 stores the received audio video signal 250. The first processing module 221 transcodes and packages the audio video signal 250, caches the generated streaming video file 235 in the module 222, and synchronizes the content from the buffer 222 to at least one of the edge servers 230 via the network module 223.

The edge server 230 receives the streaming video file 235. The second processing module 231 performs network coding on the streaming video file 235. The network coding program 234 is used to perform coding to a fixed-length streaming video file 235 and output multiple pieces of coded information 244.

The network coding program 234 of the present embodiment is to process the entire streaming video file 235. The network coding program 234 segments the streaming video file into multiple equal-sized clips. The coding process is comprised of but not limited to: selecting multiple clips randomly, and performing random linear combination on the clips over a Galois Field to output a piece of coded information 244. The size of a piece of coded information 244 is identical to the size of a clip.

Unlike the physical segmentation method in the prior art, the network coded streaming video file 235 is not segmented into data blocks at fixed offsets, but is encoded to different pieces of the coded information 244. The edge server 230 of the present embodiment can be regarded as the source of a network coding architecture, the player node 240 can be regarded as the channel of the network coding architecture. The edge server 230 performs network coding on the streaming video file, and then sends the generated coded information 244 to the connected player node 240. In other words, the transmission of the coded information 244 in the present embodiment adopts network coding transmission.

The amount of pieces of the coded information 244 is associated with the amount of the player nodes 240 connected to the edge server 230. In general, the amount of pieces of the coded information 244 is no less than the amount of the player nodes 240, allowing each player node 240 to receive one or more pieces of the coded information 244. Although the network coding in the present embodiment can output multiple pieces of code information 244, not all of the pieces of coded information 244 are needed in the decoding process as in the prior art. As long as a sufficient amount of pieces of coded information 244 is received, the player node 240 can decode the streaming video file 235 according to the coded information 244. Herein, the amount is defined as a decoding threshold. Conversely, if the amount of pieces of the received coded information 244 accumulated by the player node is less than the decoding threshold, the player node 240 requests more coded information from the edge sever 230. In other words, the player nodes 240 connected to the edge sever 230 exchange the coded information with each other.

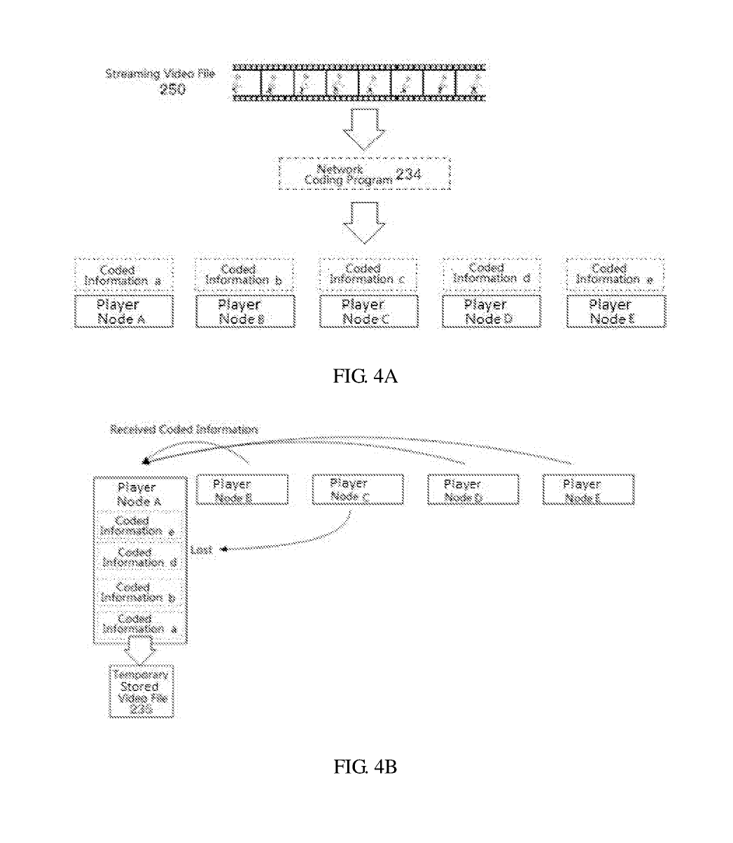

After the coded information 244 is received by its assigned player node 240, the third processing module 241 of the player node 240 requests more coded information 244 from adjacent player nodes 240, as shown in FIG. 4A. For example, the edge server 220 is connected to five player nodes 240, namely a player node A, a player node B, a player node C, a player node D, and a player node E. The player node A receives coded information a, the player node B receives coded information b, the player node C receives coded information c, the player node D receives coded information d, the player node E receives coded information e.

The player node A requests the coded information b, c, d, and e from the player nodes B, C, D, and E. Assuming that the decoding threshold is three in this example; in other words, as long as the player node A receives at least three pieces of coded information arbitrarily, the streaming video file 235 can be decoded. For example: the player node A receives the coded information b, d, e. The player node A can perform a decoding process program 245 based on the coded information b, d, e, and output the streaming video file 235, as shown in FIG. 4B.

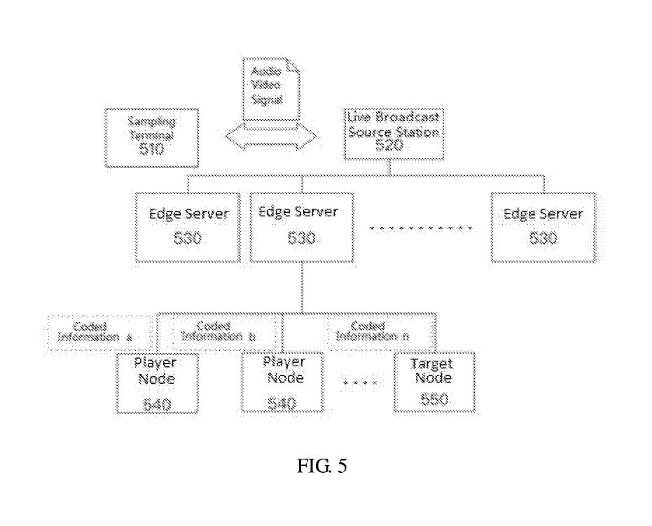

FIG. 5 shows a block diagram of the system configuration according to another embodiment of the present invention. In this embodiment, a processing system 500 comprises a sampling terminal 510, a live broadcast source station 520, a plurality of edge servers 530, a plurality of player nodes 540 and a plurality of target nodes 550. The live broadcast source station 520 is connected to the sampling terminal 510 and the edge servers 530 respectively via the network. Each of the edge severs 530 is connected to the player nodes 540 and at least one target node 550 via the network. The connection and configuration among the sampling terminal 510, player nodes 540, edge servers 530 and target nodes 550 are identical to that as mentioned above, so no redundant detail is to be repeated herein. In this embodiment, the target node 550 is externally connected to the edge server 530, and is not chosen from the current player nodes 540. The function of the target node 550 is that the target node 550 neither exchanges the coded information 244 with other target nodes 550 nor downloads the coded information 244 from other player nodes 540; instead, the target node 550 receives the coded information 244 from the edge server 530 and transmits the received coded information 244 to other player nodes 540. The target node 550 can increase the chance of receiving valid coded information 244 by the player nodes 540, and make the player nodes 540 improve the fluency of playback.

Therefore, if the player node encounters errors (e.g. network packet loss) when receiving other coded information, the player node can request the coded information from other player nodes. The player node would not receive the coded information with duplicated contents. As compared to the conventional technology, the present invention can decrease error occurrence rate in repeated requests, and accelerate the transmission and decoding of data.

While the exemplary embodiments have been described in connection with a number of embodiments and implementations, the exemplary embodiments are not so limited but cover various obvious modifications and equivalent arrangements, which fall within the purview of the appended claims. Although features of the exemplary embodiments are expressed in certain combinations among the claims, it is contemplated that these features can be arranged in any combination and order.

What is claimed is:

1. A processing system for live video streaming based on network coding and content distribution network, the processing system being applied in live video streaming over a network, comprising:
a live broadcast source station, for receiving an audio video signal and generating a streaming video file;
at least one edge server, connected to the live broadcast source station, for receiving the streaming video file from the live broadcast source station, performing network coding on the streaming video file and outputting a plurality of pieces of coded information; and
a plurality of player nodes, each connected to the edge server via the network, the player nodes being connected to each other via the network, for receiving the pieces of coded information from the edge server and exchanging the coded information with each other;
wherein each of the player nodes keeps accumulating the coded information until an amount of pieces of received coded information reaches a decoding threshold, the player nodes decode the pieces of received coded information and output the streaming video file, and if the amount of pieces of received coded information is less than the decoding threshold, the player nodes request more of the pieces of coded information from the edge server until the streaming video file is decodable.

2. The processing system of claim 1, wherein each of the player nodes receives at least one of the pieces of coded information of the streaming video file, and all of the pieces of coded information are different.

3. The processing system of claim 2, wherein each of the pieces of coded information received by each of the player nodes is smaller than the uncoded streaming video file.

4. The processing system of claim 2, wherein the encoding processing comprises: segmenting the streaming video file into a plurality of clips by linear network coding; and performing random linear combination on the clips over a Galois Field to output the pieces of coded information.

5. The processing system of claim 1, wherein each of the player nodes forwards the pieces of coded information to another player node directly from the edge server but not from other player nodes.

6. The processing system of claim 1, wherein any of the player nodes is selected as a target node, and the target node receives the pieces of coded information from the edge server but not from other player nodes or other target nodes and transmits the pieces of received coded information to the other player nodes.

7. A processing method for live video streaming based on network coding and content distribution network, the processing method being applied in live video streaming over a network, comprising steps of:
a live broadcast source station receiving an audio video signal and generating a streaming video file;
at least one edge server receiving the streaming video file from the live broadcast source station;
the edge server performing a network coding program on the streaming video file and outputting a plurality of pieces of coded information;
the edge server sending the pieces of coded information to an assigned player node among a plurality of player nodes;
the player nodes exchanging the pieces of coded information with each other;
each of the player nodes accumulating the coded information and determining whether an amount of the pieces of received coded information reaches a decoding threshold; and
if the amount of the pieces of received coded information reaches the decoding threshold, the player nodes decodes the pieces of received coded information by a decoding process program and outputs the streaming video file; or
if the amount of the pieces of received coded information is less than the decoding threshold, the player nodes request more of the pieces of coded information from the edge server until the streaming video file is decodable.

8. The processing method of claim 7, wherein each of the player nodes connected to the edge server exchanges the pieces of coded information with each other by forwarding the pieces of coded information to another player node directly from the edge server but not from other player nodes.

9. The processing method of claim 7, wherein any of the player nodes is selected as a target node, and the target node receives the pieces of coded information from the edge server but not from other player nodes or other target nodes and transmits the pieces of received coded information to the other player nodes.
